(19) United States
(12) Patent Application Publication
(10) Pub. No.: US 2013/0114206 A1
(43) Pub. Date: May 9, 2013

(54) POWER ELECTRONIC ARRANGEMENT

(71) Applicant: Dirk Schramm, Furth (DE)

(72) Inventor: Dirk Schramm, Furth (DE)

(21) Appl. No.: 13/697,482

(22) PCT Filed: Apr. 4, 2011
(86) PCT No.: PCT/EP2011/055162

§ 371 Date: Jan. 23, 2013

(30) Foreign Application Priority Data
May 12, 2010 (DE) 102010028927.2

(51) Int. Cl. H05K 7/20

(52) U.S. Cl. CPC H05K 7/20
USPC 361/688

(57) ABSTRACT

A power electronics assembly having a cooling device, one or more capacitors and one or more circuits, wherein at least one capacitor is electrically connected to at least one circuit, and wherein at least one circuit is disposed on the cooling device, wherein the power electronics assembly also exhibits a bracket having a bracket base body and at least one connecting element, provided for attachment to the cooling device, wherein at least one capacitor is accommodated on the bracket base body, in particular, placed and supported thereon, and wherein the circuit disposed on the cooling device is disposed on a surface of the cooling device facing the bracket base body.

The present invention relates to a power electronics assembly according to the preamble of Claim 1.

Known power electronics assemblies, or power electronics of the present type according to the prior art, which form at least a power converter, e.g. an AC converter, and, for example, can be used in a (hybrid) motor vehicle as a power supply for an electric motor and as an energy recovery system for energy in an energy store. The known power electronics assemblies exhibit a cooling device having a cooling plate and assemblies or circuits, which usually implemented on circuit boards (boards), e.g. a circuit board having a control unit (control board), an EMC circuit board (EMC board), a driver circuitry (driver) and one or more (power) capacitors, e.g. for the intermediate storage of, e.g., recovered energy.

Power electronics assemblies of this type are constructed such that, by way of example, the (power) capacitors provided for intermediate storage are disposed on one side of the cooling plate (frequently the bottom), while the remaining components are disposed on the other side of the cooling plate (frequently the top). The capacitors must be electronically connected to the components disposed on the other side of the cooling plate. The electronic connection is obtained by means of corresponding holes in the cooling device and the cooling plate.

Because the cooling devices usually use liquids as a cooling agent, the holes are accordingly laid out in an extensive manner, wherein there is the chance that with a leak in the holes, cooling fluid may infiltrate the electronic connections and, thereby, the region of the electronic components. If a leak occurs, (in particular in the region of the holes), then the entire power electronics assembly (on both sides of the cooling device) must be opened and all holes will require a new seal. This is time consuming and cost-intensive.

Furthermore, from DE 10 2004 013 477 A1 a bracket in the form of a bracket platform for components of a power electronics and a power electronics module having a corresponding bracket platform are known, in which all components are disposed on one side of the bracket platform, which is made of a fiber composite material. In this case, numerous (a total of twelve) capacitor elements (the components of the module requiring heat dissipation) are disposed in a first module region and are combined to form a capacitor element bundle, forming a first functional group of the module. The capacitor element bundle is covered by a preferably metal hood, and insulated from said hood in that an intermediary space, formed between the capacitor element bundle, the bracket platform, and the hood, is filled, e.g., with a molecular sieve granulate filling.

This filling provides a thermal connection of the capacitor element bundle to the hood, and, thereby, for the discharge of the heat occurring during operation. The filling also serves as a moisture and noise protection. Other suitable fillings, in particular filling compounds, or resins, or granulates may also be used for the filling. In addition, sheet metal parts may be attached for the dissipation of heat. The switchgears are disposed, however, outside of the first module region, protected by the hood, and in the embodiment described in DE 10 2004 013 477 A1, lie open. The electric connection between the capacitor element bundle, disposed beneath the hood, and the other electric, or electronic, respectively, components occurs via a corresponding hole. There is a complicated construction, having an execution prone to error, in this power electronic module as well. In the case of damage, the entire granulate filling must be removed. This means large time expenditure. Furthermore, the possibility for heat dissipation is limited, because the heat of the capacitor bundle is dissipated exclusively through air circulation about the hood.

Based on the preceding explanation of the prior art, it is the objective of the present invention to produce a power electronics assembly having an increased ease of maintenance and repair, as well as a reduction of the possible sources of error, and is thereby able to ensure operation without interruption to the greatest degree possible.

This objective is attained by means of a power electronics assembly having the characteristics of Claim 1.

According to the invention, a power electronics assembly is proposed, having a cooling device, one or more (power) capacitors and one or more circuits, wherein at least one capacitor is connected electrically to at least one circuit, and wherein at least one circuit is disposed on the cooling device, wherein the power electronics assembly also includes a bracket having a bracket base body and at least one connecting element, provided for attachment to the cooling device, wherein at least one capacitor is accommodated on the bracket base body, in particular, placed and supported thereon, and wherein the circuitry disposed on the cooling device is disposed on a surface of the cooling device facing the bracket base body.

According to one aspect of the invention, the capacitor disposed on the bracket base body is disposed on a surface of the bracket base body facing the cooling device.

According to another aspect of the power electronics assembly according to the invention, the bracket base body is designed such that it is integrated with the at least one connecting element.

It is further proposed in accordance with the invention that the bracket base body have a first accommodation region for accommodating, in particular for placing and supporting thereon, the at least one capacitor.

It is further proposed that the bracket base body have a second accommodation region for accommodating and/or attaching one of more circuit boards.

According to another aspect of the invention, the bracket base body, the at least one connection element, and the surface of the cooling device facing the bracket body, form an electronics compartment, in which all electronic components of the power electronics assembly are disposed.

It is also proposed that the bracket base body and the at least one connecting element are made of aluminum.

It is further proposed that the bracket is connected to the cooling device in a thermo-conductive manner.

According to another aspect of the invention, the bracket is electro-conductively connected to the cooling device.

Likewise, according to another aspect of the invention, the cooling device exhibits a cooling plate and a cooling device base body, on which a first and a second coolant connection is disposed.

It is also proposed that the circuitry disposed on the cooling device be disposed on the cooling plate, in particular, attached to said plate.

Other characteristics and advantages of the invention can be derived from the following description of a possible embodiment of the invention, based on the attached drawing, which shows details substantial to the invention, and from the claims. The individual characteristics can each be realized in and of themselves, or in plural, in arbitrary combinations, in a variation on the invention.

A preferred embodiment of the invention shall be explained below in greater detail, based on the attached drawing. It shows:

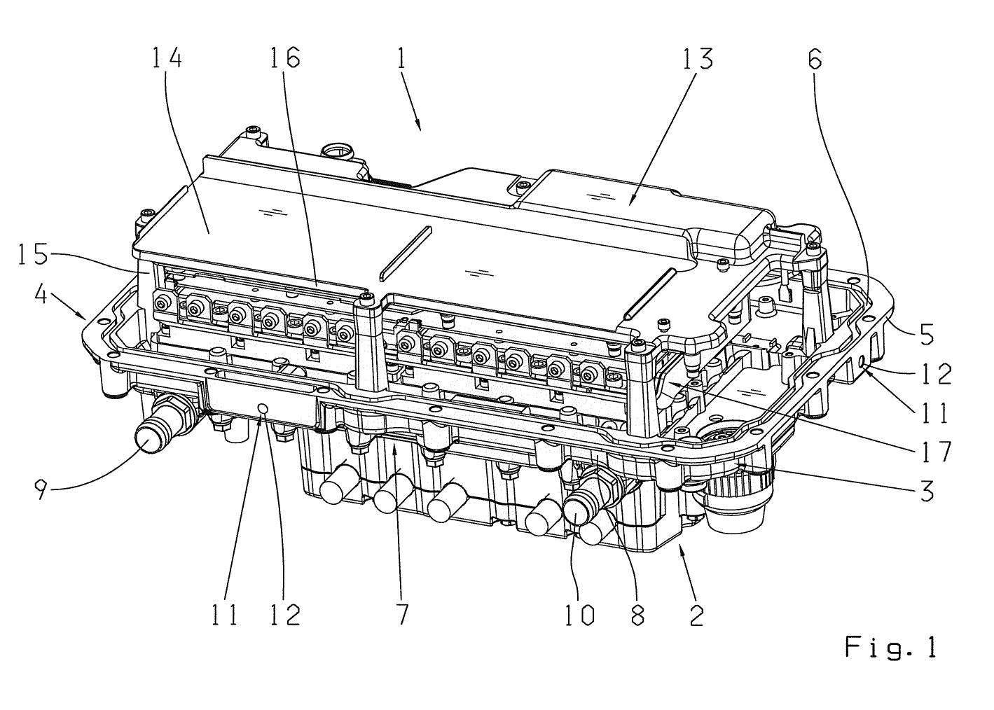

FIG. 1 A perspective view of a possible embodiment of a power electronics assembly according to the invention.

The power electronics assembly 1 according to the invention shown in an exemplary manner in FIG. 1, having, for example, at least one power converter, e.g., an AC converter and/or e.g., a DC converter, is, for example, intended for use in a motor vehicle, e.g., as the power electronics for conversion of electric energy to a voltage and frequency suitable for an electric drive motor of a hybrid vehicle. Aside from this, the power electronics assembly 1 is designed, e.g., for intermediate storage of energy recovered from the drive motor (generator mode of the drive motor).

The power electronics assembly 1 has a cooling device 2 having a cooling plate 3 being designed basically in the form of a rectangle, and an extended edge 5 facing toward a first (upper) surface 4, in which a groove is formed over the entire circumference of the edge 5 for receiving a (not shown) housing lid. A cooling device base body 8 is disposed on a second (lower) surface 7 of the cooling plate 3, which is thermo-conductively connected to the cooling plate 3.

The cooling device base body 8 exhibits a (not shown) cavity in the material, forming a channel, which is laid out such that a coolant, e.g., coolant water in the described embodiment, can flow through it, and thereby providing a cooling effect to the cooling device base body 8, and the cooling plate 3 connected thereto. The cooling device base body 8 also exhibits a first coolant water connection 9, which serves in the described embodiment as a coolant water flow line. For discharging the heated coolant, the cooling device base body 8 also exhibits a second coolant connection 10, which serves as the coolant return flow line in the described embodiment. The cooling plate 3 in the described embodiment is attached, by means of suitable fastening components in the form of screws 11, to the cooling device base body 8.

GND connection devices 11 are provided on the cooling plate 3, serving to connect the cooling plate 3 to the vehicle mass. Each of the GND connection device 11 has a contact surface and a recess 12 having an internal threading, such that different types of cable shoes or other contact devices can be securely fastened thereto (e.g. by means of screws).

A bracket 13 is disposed, according to the invention, on the first (upper) surface 4 of the cooling plate 3. The bracket 13 exhibits a bracket base body 14 provided for accommodating and/or supporting electronic components of the power electronics assembly 1, constructed basically in the shape of a plate. The components disposed on, or accommodated by, respectively, the bracket base body 14 are, in the described embodiment, according to the invention, at least one capacitor, in particular one or more performance capacitors, e.g., for the intermediate storage of energy. Aside from this, in particular, one or more assembled circuit boards (boards; one EMC and one control board (control circuits) can be accommodated on the bracket base body 14. Other components of the power electronics assembly 1, in particular a circuitry (e.g., an AC converter) for the power electronics, a driving stage, or a drive circuit 17, respectively, is disposed on the (upper) surface 4 of the cooling plate 3 facing the bracket base body 14.

The exhaust heat of the components disposed on the bracket base body 14, in particular the (power) capacitor, is discharged to the cooling device 2, for which reason the bracket 13 exhibits bridging connecting elements 15, which are provided for attachment to the cooling plate 3. The attachment occurs via suitable attachment elements in the form of screws (not visible in FIG. 1), whereby a plug connection is also conceivable as an alternative thereto.

The connecting elements 15 are integrated in the described embodiment in the bracket base body 14. As an alternative thereto, it would also be conceivable to produce the connecting elements 15 as separate components, and to attach said elements to the bracket base body 14 by means of suitable fastening possibilities (screws, welding, gluing, etc.). The bridge-like connecting elements 15 extend at basically a right angle away from the bracket base body 14 toward the cooling plate 3.

The components disposed on, or respectively accommodated by the bracket base body 14, are disposed, in the described embodiment, on a surface of the bracket base body 14 facing away from the cooling plate 3 in corresponding accommodation regions. The at least one capacitor is disposed in a first accommodation region. This is supported, in particular, on the bracket base body 14, and brought into contact with said bracket base body. In this manner, a heat dissipation of the capacitor to the bracket base body 14, as well as via the connecting elements 15 to the cooling plate 3, is ensured. The heat transferred to the cooling plate 3 is then discharged by means of the cooling device 2. In this manner, the bracket base body 14, the connecting elements 15, and the side of the cooling device 2 that faces the bracket base body 14 form, or define, respectively, an electronics compartment, in which other electronic components of the power electronics assembly are disposed. It is to be understood that a configuration of numerous (power) capacitors on the bracket base body 14, in particular in the first accommodation region, is also conceivable. The accommodation region could, alternatively, also be disposed on a surface of the bracket base body 14 facing the cooling plate.

Moreover, a second accommodating region is provided for accommodating assembled circuit boards or circuits on the surface 16 of the bracket base body 14 facing the cooling plate 3, in which, in particular, a control circuit board (control board) and/or an EMC board is disposed. For this, corresponding fastening possibilities (not shown in the figure) in the form of recesses having internal threading are provided, to which the circuit boards can be attached by means of screws. Fastening possibilities for snapping the circuit boards in place, or for another type of accommodating or fastening of said circuit boards, are also conceivable.

The bracket 13 is, as already mentioned, connected to the cooling plate 3 and to the cooling device 2. As a result, the heat discharge from the bracket 13 to the cooling device 2 is ensured. The materials, from which the bracket base body 14 and the connecting elements 15 are made, can be adapted to the quantity of heat that is to be discharged, wherein it is conceivable that the bracket base body 14 and the connecting elements 15 are made of the same material, or of different materials. In the described embodiment, in which the bracket base body 14 and the connecting elements 15 are integrated, the bracket base body 14 and the connecting elements 15 are made of aluminum, which has a high degree of thermo-conductivity and therefore also ensures a good heat dissipation for larger quantities of heat to be dissipated. Alternatively, all other suitable materials, such as metallic materials, composite materials, etc. can also, as a rule, be used.

Because the bracket 13 (bracket base body 14 and the connecting elements 15) is made of aluminum, the bracket 13 is therefore also electro-conductively connected to the cooling plate 3, and therefore, the cooling device 2. In this manner it is ensured that the bracket 13 exhibits the same electric potential as the cooling plate 3, or the cooling device 2, respectively. It should be noted at this point that the connecting elements 15 are formed on, or attached to, the edge 16 (circumferential edge) of the bracket base body 14.

In summary, it can be concluded that in contrast to the prior art, all electronic components of the power electronics assembly 1, in particular all power electronics components, are disposed within a single compartment, or respectively, electronics component compartment, and not on the opposite side of the bracket (separated by the cooling device). As a result, there is a short connection distance between the individual components, in particular between capacitor(s) and circuit boards, e.g., in particular also between the driving stage(s) and the control board, which also leads to a more limited tendency to electronic disruptions, or respectively, to a more limited generation of electronic disturbances. Furthermore, a construction of this type ensures a compact structural size. The connecting elements 15 serve as the heat dissipation and as connection to the mass, as a result of which the capacitors can be cooled off despite a spatial separation from the coolant in the mass, which is required by an implementation of power electronics, for example, in the frame of a vehicle.

A more compact construction is ensured with a construction of this type, as has already been mentioned. Fewer interfaces are needed, resulting in a reduction in costs, and a reduction in the possible sources for error. Moreover, an insertion of electronic wiring or connections through the cooling device is not needed, which results in the elimination of corresponding seals, and corresponding tendency to errors that is resulted from leaks is reduced. For repairs, one can also limit said repairs to opening only the electronic components compartment, while the cooling system may remain untouched.

### REFERENCE SYMBOLS

1 power electronics assembly
2 cooling device
3 cooling plate
4 first (upper) surface of the cooling plate
5 edge of the cooling plate 3
6 groove
7 second (lower) surface of the cooling plate
8 cooling device base body
9 first coolant water connection
10 second coolant water connection
11 GND connection device
12 hole
13 bracket
14 bracket base body
15 connecting element
16 edge of the bracket base body
17 driver circuitry

1. A power electronics assembly, comprising:
a cooling device;
a bracket comprising a bracket base body and a connecting element for attaching the bracket to the cooling device; and
one or more capacitors, wherein a capacitor is accommodated on the bracket base body and a capacitor is electrically connected to a circuit;
a circuit being on a surface of the cooling device facing toward the bracket base body in a first receiving area
wherein the bracket base body comprises a second receiving area for receiving one or more printed circuit boards, and
wherein the bracket base body, the connecting element, and the surface of the cooling device form an electronics compartment in which electronic components of the power electronics assembly are arranged.

2.-11. (canceled)

12. The power electronics assembly according to claim 1 wherein the bracket base body is integrated with the connecting element.

13. The power electronics assembly according to claim 1 wherein the bracket base body and the connecting element are made of aluminum.

14. The power electronics assembly according to claim 1 wherein the connecting element is thermally conductive.

15. The power electronics assembly according to claim 1 wherein the connecting element is electrically conductive.

16. The power electronics assembly according to claim 1 wherein the cooling device comprises a plate and a main body, the main body having a first water connection and a second water connection.

17. The power electronics assembly according to claim 16 wherein the circuit is located on the plate.
